(19) United States
(12) Patent Application Publication
(10) Pub. No.: US 2024/0043274 A1
(43) Pub. Date: Feb. 8, 2024

(54) Blue indium phosphide quantum dot and preparation method therefor, electroluminescent device, and display device

(71) Applicant: SUZHOU XINGSHUO NANOTECH CO., LTD., Suzhou, Jiangsu (CN)

(72) Inventors: Yuliang SHAN, Suzhou, Jiangsu (CN); Yunjun WANG, Suzhou, Jiangsu (CN)

(21) Appl. No.: 18/266,611

(22) PCT Filed: Dec. 8, 2021
(86) PCT No.: PCT/CN2021/136565

§ 371 Date: Jun. 12, 2023

(30) Foreign Application Priority Data
Dec. 15, 2020 (CN) 202011468865.2

(51) Int. Cl. C01B 25/08; C09K 11/08; C09K 11/62; C01G 15/00; H10K 50/115

(52) U.S. Cl. CPC C01B 25/087; C09K 11/0883; C09K 11/62; C01G 15/00; H10K 50/115

(57) ABSTRACT

Disclosed in the present disclosure is a preparation method for a blue indium phosphide quantum dot. According to the present disclosure, at a predetermined temperature, the kernel of the indium phosphide quantum dot and the first zinc precursor are mixed, and the thiol is added for reaction to form the second mixed solution containing an intermediate product of the indium phosphide quantum dot; and then the anionic precursor having a lower reaction activity than the thiol is added for continuous reaction to obtain the blue indium phosphide quantum dot having a wavelength range of 450-480 nm. The blue indium phosphide quantum dot has a pure wavelength; and when the blue indium phosphide quantum dot is applied to an electroluminescent device, the brightness is greater than 100 nits, and external quantum efficiency is high up to 1.8%, and the application range of the indium phosphide quantum dot is widened.

### CROSS REFERENCE TO RELATED APPLICATIONS

This application is a national application of PCT/CN2021/136565, filed on Dec. 8, 2021. The contents of PCT/CN2021/136565 are all hereby incorporated by reference.

### TECHNICAL FIELD

The present disclosure relates to the field of nanotechnologies, in particular to a blue indium phosphide quantum dot and a preparation method therefor, an electroluminescent device, and a display device.

### BACKGROUND

A quantum dot has the advantages of being narrow in half-peak width and high in Quantum Yield (QY), and has huge application prospects in fields such as display and lighting. Compared with a group II-VI element quantum dot such as a cadmium selenide quantum dot and a cadmium telluride quantum dot, a group III-V element quantum dot represented by an indium phosphide quantum dot does not contain highly toxic heavy metal elements such as cadmium, which is wider in application range and is gradually receiving the attention of the scientific research community and industry.

However, it is difficult to synthesize the blue indium phosphide quantum dot in the related art, and the quality of the synthesized quantum dot is poor. When the quantum dot is applied to an electroluminescent device, the device has poor conductivity, low efficiency and low brightness, which cannot meet application requirements, completely. Therefore, optimizing a method for preparing an indium phosphide quantum dot, especially a method for preparing a blue indium phosphide quantum dot, has great significance.

### SUMMARY

In view of this, the present disclosure is intended to provide a blue indium phosphide quantum dot and a preparation method therefore, an electroluminescent device prepared by the blue indium phosphide quantum dot, and a display device. The blue indium phosphide quantum dot has a pure wavelength, and high in brightness and external quantum efficiency when being applied to the electroluminescent device.

In order to achieve the above objective, the present disclosure provides the following technical solutions.

A first objective of the present disclosure is to provide a preparation method for a blue indium phosphide quantum dot, the method including the following steps.

At S1, the kernel of an indium phosphide quantum dot and a first zinc precursor are mixed, so as to form a first mixed solution.

At S2, at 300-340° C., thiol is added to the first mixed solution for reaction, so as to form a second mixed solution containing an indium phosphide quantum dot intermediate product.

At S3, at 240-340° C., an anionic precursor is added to the second mixed solution for reaction, so as to obtain a blue indium phosphide quantum dot.

The reaction activity of the anionic precursor is lower than the reaction activity of the thiol.

Specifically, a mole ratio of the kernel of the indium phosphide quantum dot to the first zinc precursor is 1:(10-100).

Preferably, a mole ratio of the first zinc precursor to the thiol is 1:(1-5).

Specifically, a mole ratio of the thiol to the anionic precursor is 1:(2-10), excluding 1:2; and a reaction temperature in S3 is 280-340° C., excluding 280° C.

Specifically, a mole ratio of the thiol to the anionic precursor is 1:(0-2), excluding 1:0; and/or a reaction temperature in S3 is 240-280° C.

Specifically, the first zinc precursor is not decomposed into zinc oxide above 300° C.

Preferably, the first zinc precursor is zinc halide or zinc fatty acid.

Specifically, the anionic precursor is a liganded or unliganded solution of selenium and/or sulfur.

Specifically, a preparation method for the kernel of the indium phosphide quantum dot includes: mixing an indium precursor, a phosphorous precursor, a second zinc precursor and an organic solvent, and performing reaction at 110-160° C., so as to obtain a solution containing the kernel of the indium phosphide quantum dot; and obtaining the kernel of the indium phosphide quantum dot by means of purification, where a chemical structural formula of the phosphorous precursor is represented as M-(O—C≡P)ₙ, and M is a metal element, n is 1, 2 or 3; preferably, the M is one of the metal elements Li, Na, K, Zn and Ga; and more preferably, the phosphorous precursor is represented as Li—O—C≡P, Na—O—C≡P, K—O—C≡P, Zn—(O—C≡P)₂ or Ga—(O—C≡P)₃.

A second objective of the present disclosure is to provide a blue indium phosphide quantum dot. The blue indium phosphide quantum dot is obtained by means of the preparation method; and the wavelength of the blue indium phosphide quantum dot is 450-480 nm.

A third objective of the present disclosure is to provide an electroluminescent device. The electroluminescent device includes a light-emitting layer. The foregoing blue indium phosphide quantum dot is used as the light-emitting layer; and the external quantum efficiency of the electroluminescent device is greater than 0.5%, and the maximum brightness is greater than 100 nits.

A fourth objective of the present disclosure is to provide a display device. The display device includes the foregoing electroluminescent device.

Compared with the related art, the present disclosure has at least the following advantages. By means of the preparation method of the present application, at a predetermined temperature, the kernel of the indium phosphide quantum dot and the first zinc precursor are mixed, and the thiol is added for reaction to form the second mixed solution containing an intermediate product of the indium phosphide quantum dot; and then the anionic precursor having a lower reaction activity than the thiol is added for continuous reaction to obtain the blue indium phosphide quantum dot having a wavelength range of 450-480 nm. The blue indium phosphide quantum dot has a pure wavelength, and high in brightness (which is greater than 100 nits) and high in external quantum efficiency (which is up to 1.8%) when being applied to the electroluminescent device, such that an application range of the indium phosphide quantum dot is widened.

### BRIEF DESCRIPTION OF THE DRAWINGS

In order to illustrate the technical solutions in the embodiments of the present disclosure or technical solutions in the related art more clearly, the drawings used in the technical description of the embodiments will be briefly described below. It is apparent that the drawings in the following descriptions are merely some embodiments of the present disclosure. Other drawings can be obtained from those skilled in the art according to these drawings without any creative work.

FIG. 1 shows the absorption spectrum of a blue indium phosphide quantum dot solution according to Embodiment 1.

FIG. 2 shows the fluorescence emission spectrum of a device prepared from a blue indium phosphide quantum dot solution according to Embodiment 1.

FIG. 3 shows the voltage-EQE change diagram of a prepared electroluminescent device according to Embodiment 1.

FIG. 4 shows the voltage-brightness change diagram of a prepared electroluminescent device according to Embodiment 1.

FIG. 5 shows the transmission electron microscope diagram of a blue indium phosphide quantum dot solution according to Embodiment 1.

FIG. 6 shows the voltage-EQE change diagram of a prepared electroluminescent device according to Embodiment 2.

FIG. 7 shows the voltage-brightness change diagram of a prepared electroluminescent device according to Embodiment 2.

### DETAILED DESCRIPTION OF THE EMBODIMENTS

The technical solutions in the embodiments are described below in detail with reference to the implementations of the present application. It should be noted that this implementation is only part of the implementations and not all of the implementations.

As expressed herein, for example, when preceded or followed by a list of elements, “at least one (of)” modifies the entire list of elements without modifying individual elements of the list. If not otherwise defined, all terms in the specification (including technical and scientific terms) may be defined as commonly understood by those skilled in the art. Terms defined in commonly-used dictionaries are to be interpreted in a manner consistent with their meaning in the context of the relevant field and the present disclosure, and are not to be interpreted in an ideal manner or too broadly, unless clearly defined. In addition, unless expressly described to the contrary, when the words “comprising” and “including” are used in this specification, it indicates there are stated features, regions, integrations, steps, operations, elements, and/or components, but does not preclude the presence or addition of one or more other features, regions, integrations, steps, operations, elements, components, and/or a combination thereof. Accordingly, the above wording will be understood to imply the inclusion of the stated elements, but not the exclusion of any other elements.

As used herein, the term “and/or” includes any and all combinations of one or more of relevant listed items. The term “or” means “and/or”.

It is understandable that, the terms first, second, third and the like may be used herein to describe various elements, components, regions, layers and/or portions, but these elements, components, regions, layers and/or portions are not limited by these terms.

As used herein, “about” or “approximately” includes the stated value and implies an acceptable range of deviation from a specified value as determined by those of ordinary skilled in the art, taking into account the measurement under discussion and the error associated with the measurement of a specified quantity (that is, the limitations of a measurement system). For example, “about” may mean that the deviation from the stated value is within one or more standard deviations, or within ±10%, 5%.

In the related art, the synthesis of a blue indium phosphide quantum dot is difficult, the wavelength of the indium phosphide quantum dot is hard to adjust and control, and in particular, it is difficult to prepare the blue indium phosphide quantum dot; and in order to obtain the indium phosphide quantum dot with a blue wavelength, the size of the indium phosphide quantum dot needs to be controlled first, resulting in low brightness and poor external quantum efficiency when the indium phosphide quantum dot is applied to an electroluminescent device, such that application requirements cannot be met.

In order to solve the problems in the related art, the present disclosure provides a new preparation method for a blue indium phosphide quantum dot. The prepared blue indium phosphide quantum dot has a pure wavelength; the wavelength ranges from 450 to 480 nm; a half-peak width is less than 50 nm; and QY is greater than 40%.

The preparation method for a blue indium phosphide quantum dot specifically includes the following steps.

First, the step of preparing the kernel of the indium phosphide quantum dot: mixing an indium precursor (indium halide), a phosphorous precursor (a feeding molar weight being greater than a feeding molar weight of the indium precursor), a second zinc precursor (zinc halide) and a ligand solvent, and performing reaction at 110-160° C., so as to obtain a solution containing the kernel of the indium phosphide quantum dot; and then obtaining the kernel of the indium phosphide quantum dot by means of purification. A chemical structural formula of the phosphorous precursor is represented as M-(O—C≡P)ₙ, where M is one of metal elements Li, Na, K, Zn and Ga, and n is 1, 2 or 3 (it is to be noted that, the value of n depends on the valence state of the M, for example, if the M is Li, the n is 1; and if the M is Zn, n is 2). The purification method is a common purification method in the related art, which is not limited herein, as long as the methods can achieve a purification effect. Next, the reaction is continuously performed by means of the following steps.

At S1, the kernel of the indium phosphide quantum dot and a first zinc precursor are mixed, so as to form a first mixed solution.

At S2, at 300-340° C., thiol is added to the first mixed solution for reaction, so as to form a second mixed solution containing an indium phosphide quantum dot intermediate product.

At S3, at 240-340° C., an anionic precursor is added to the second mixed solution for reaction, so as to obtain a blue indium phosphide quantum dot. The reaction activity of the anionic precursor is lower than the reaction activity of the thiol.

The inventor discovered that, since a surface ligand of the intermediate product of the indium phosphide quantum dot is the thiol with high activity, and if the indium phosphide quantum dot is directly applied to an electroluminescent device, the conductivity of the device is poor, and the external quantum efficiency is low. Therefore, the inventor adds the anionic precursor of which reaction activity is lower than that of the thiol and steric hindrance is less than that of the thiol into the second mixed solution to perform reaction at a preset temperature, so as to cause the anionic precursor to have higher reaction energy; and the anionic precursor with small steric hindrance makes the quantum dot more conductive, such that the blue indium phosphide quantum dot with good electroluminescence performance is formed.

In the present application, the first zinc precursor which is not decomposed above 300° C. is preferred, and is zinc halide or zinc fatty acid. Preferably, the first zinc precursor is selected from at least one of zinc chloride, zinc stearate, zinc undecylenate, zinc tetradecanoate or zinc oleate.

The anionic precursor is a liganded or unliganded solution of selenium and/or sulfur. A shell layer of the indium phosphide quantum dot is at least one of ZnS, ZnSe or ZnSeS. The inventor discovered that, generating ZnS and/or ZnSe and/or ZnSeS shell layers on the surface of the indium phosphide quantum dot facilitates the obtaining of the indium phosphide quantum dot with better stability and more excellent electrical properties.

A sulfur precursor (the foregoing liganded or unliganded solution of sulfur) is at least one of an organophosphorus complex of sulfur, a fatty amine compound of sulfur or a long-chain alkene solution of sulfur; a selenium precursor (the foregoing liganded or unliganded solution of selenium) is at least one of an organophosphorus complex of selenium, a fatty amine compound of selenium or a long-chain alkene solution of selenium.

In the present disclosure, M-(O—C≡P)ₙ is used as a new phosphorus source of the kernel of the indium phosphide quantum dot, so as to prepare the kernel of the indium phosphide quantum dot.

Due to the introduction of the metal element M, the kernel of the indium phosphide quantum dot composed of In, Zn, P and metal element M is prepared, such that the optical performance of the subsequently-obtained indium phosphide quantum dot is further optimized. Preferably, the phosphorous precursor is Li—O—C≡P, Na—O—C≡P, K—O—C≡P, Zn—(O—C≡P)₂, or Ga—(O—C≡P)₃.

In order to obtain the indium phosphide quantum dot with a blue wavelength, in the present disclosure, a mole ratio of the kernel of the indium phosphide quantum dot to the first zinc precursor is selected to be 1:(10-100); and a mole ratio of the first zinc precursor to the thiol is 1:(1-5). By means of the selection of the mole ratio of the above raw materials and the reaction at the preset temperature, the size of the kernel of the indium phosphide quantum dot may be controlled, so as to obtain the kernel of the indium phosphide quantum dot with a blue wavelength.

The kernel of the purified indium phosphide quantum dot is mixed with the first zinc precursor and then reacts with the thiol with large reaction activity at a high temperature, such that the second mixed solution that contains the indium phosphide quantum dot intermediate product with a pure wavelength and the value of a fluorescence emission peak ranging from 450 to 480 nm may be obtained. In S2 of the present application, selecting the high temperature reaction condition and the thiol with large reaction activity is to make the ZnS shell layer rapidly coated on the kernel of the blue indium phosphide, so as to prevent the kernel of the blue indium phosphide from continuously growing, thereby obtaining the intermediate product of the indium phosphide quantum dot with a pure wavelength.

In an implementation of the present disclosure, a mole ratio of the thiol to the anionic precursor is 1:(2-10), excluding 1:2; and a reaction temperature in S3 is 280-3400° C., excluding 280° C. By means of applying the blue indium phosphide quantum dot prepared by the method to the electroluminescent device, the EQE of the device reaches more than 1.1%. The inventor finds that, in this implementation, by means of the high temperature condition, the coordination bond between thiol and metal is broken; and then the anionic precursor can be subjected to a coordination reaction with metal by controlling the user amount of the anionic precursor to be much greater than the user amount of the thiol. Specifically, there are the following situations.

First situation: the thiol which is formed outside the kernel of the indium phosphide quantum dot and subjected to the coordination reaction with the first zinc precursor is completely replaced by the anionic precursor, so as to only form a shell layer, which is a first shell layer which formed by the coordination reaction of anionic precursor with the first zinc precursor, outside the kernel of the indium phosphide quantum dot.

Second situation: the thiol which is formed outside the kernel of the indium phosphide quantum dot and subjected to the coordination reaction with the first zinc precursor is partially replaced by the anionic precursor, so as to form a second shell layer which formed by the coordination reaction of the anionic precursor with the first zinc precursor and the coordination reaction of the thiol with the first zinc precursor respectively. The anionic precursor in the second shell layer and a coordination bonding unit of the first zinc precursor are mutually doped, and the thiol and the coordination bonding unit of the first zinc precursor are mutually doped.

Third situation: the thiol which is formed outside the kernel of the indium phosphide quantum dot and subjected to the coordination reaction with the first zinc precursor is partially replaced by the anionic precursor, so as to form a second shell layer which formed by the coordination reaction of the anionic precursor with the first zinc precursor and the coordination reaction of the thiol with the first zinc precursor respectively. The anionic precursor in the second shell layer and a coordination bonding unit of the first zinc precursor are mutually doped, and the thiol and the coordination bonding unit of the first zinc precursor are mutually doped. In addition, the anionic precursor is subjected to the coordination reaction with the redundant first zinc precursor, so as to form a third shell layer coated outside the second shell layer.

In another implementation of the present disclosure, the mole ratio of the thiol to the anionic precursor is 1:(0-2), excluding 1:0; and/or the reaction temperature in S3 is 240-280° C. By means of applying the blue indium phosphide quantum dot prepared by the above conditions to the electroluminescent device, the EQE of the device reaches 0.5-1.1%, and the conductivity is much better than the EQE of devices in the related art.

Fourth situation: the inventor finds that, when the addition of the anionic precursor is insufficient and/or the reaction temperature is insufficient, the thiol which is formed outside the kernel of the indium phosphide quantum dot and subjected to the coordination reaction with the first zinc precursor cannot be replaced by the anionic precursor at all. The anionic precursor is subjected to the coordination reaction with the redundant first zinc precursor, so as to form a fourth shell layer, and the fourth shell layer is coated on the shell layer that is formed by means of the coordination reaction of the thiol and the first zinc precursor.

Since the third shell layer or the fourth shell layer is formed, the redundant first zinc precursor is required to participate in the reaction. Preferably, in S3, the first zinc precursor is added again. In the present disclosure, enough first zinc precursor can be added at one time in S1, or the first zinc precursor may be added in batches in S1 and S3, respectively. The manner of adding the first zinc precursor in batches makes reaction in each step more responsive.

In order to further improve the optical performance of the prepared blue indium phosphide quantum dot, after the blue indium phosphide quantum dot is obtained, steps of removing unreacted raw materials and other impurities are further included, specifically including isolation and purification. These steps are well known methods in the art and are not described herein again.

A third objective of the present disclosure is to provide an electroluminescent device. The electroluminescent device includes a light-emitting layer. The foregoing blue indium phosphide quantum dot is used as the light-emitting layer; and the external quantum efficiency of the electroluminescent device is greater than 0.5%, and the maximum brightness is greater than 100 nits. The preparation method uses a method well known in the art and is not described herein again.

A fourth objective of the present disclosure is to provide a display device. The display device includes the foregoing electroluminescent device.

The present application is described below in detail with reference to specific embodiments.

### Embodiment 1

This embodiment provided a preparation method for a blue indium phosphide quantum dot, where the following steps was included in specifically.

A step of preparing the kernel of an indium phosphide quantum dot included: 0.5 mmol of indium chloride, 0.75 mmol of Na—O—C≡P, 1 mmol of zinc chloride and 10 mL of oleylamine was mixed, reaction was performed at 160° C. for 30 min, so as to obtain a solution containing the kernel of the indium phosphide quantum; and then the kernel of the indium phosphide quantum dot was obtained by means of purification for later use.

At S1, 40 mL of a zinc stearate in octadecene solution with the concentration being 0.5 M was prepared; vacuuming was performed at 120° C. for 30 min, then converted to argon; a temperature was heated to 240° C.; and one tenth of the kernel of the prepared indium phosphide quantum dot was added, so as to form a first mixed solution.

At S2, 1-dodecanethiol was added dropwise at 240° C. for reaction, and the addition was performed at 5 mL/h for 1 hour; and at the same time, the temperature was continuously heated to 310° C. and maintained until the addition of the 1-dodecanethiol was completed, so as to form a second mixed solution.

At S3, the temperature was cooled to 290° C.; TOP-S (a concentration being 2 M, a trioctyl phosphine solution of sulfur) was added dropwise to the second mixed solution for reaction, and the addition was performed at 10 ml/h for 2 hours; cooling was performed; and purification was performed, so as to obtain the blue indium phosphide quantum dot. An electroluminescent device and a display device were prepared from the blue indium phosphide quantum dot obtained by means of preparation; and the preparation method uses a conventional method in the related art, and was not described herein again.

### Embodiment 2

This embodiment provided a preparation method for a blue indium phosphide quantum dot, and used a nucleation mode same as Embodiment 1. The remaining steps were as follows.

At S1, 40 mL of a zinc stearate in octadecene solution with the concentration being 0.05 M was prepared; vacuuming was performed at 120° C. for 30 min, then converted to argon; a temperature was heated to 240° C.; and one tenth of the kernel of the prepared indium phosphide quantum dot was added (a mole ratio of the kernel of the indium phosphide quantum dot to a first zinc precursor being 1:40), so as to form a first mixed solution.

At S2, 1-dodecanethiol was added dropwise at 310° C. for reaction, and the addition was performed at 2 mL/h for 1 hour; and at the same time, and the temperature was maintained until the addition of the 1-dodecanethiol was completed, so as to form a second mixed solution.

At S3, the temperature was cooled to 290° C.; a trioctyl phosphine solution of sulfur (the concentration being 2 M) was added dropwise to the second mixed solution for reaction, and the addition was performed at 10 ml/h for 2 hours; cooling was performed; and purification was performed, so as to obtain the blue indium phosphide quantum dot. An electroluminescent device and a display device were prepared from the blue indium phosphide quantum dot obtained by means of preparation; and the preparation method uses a conventional method in the related art, and was not described herein again.

### Embodiment 3

This embodiment provided a preparation method for a blue indium phosphide quantum dot, which was basically the same as Embodiment 2. The difference lied in that, the addition of the first zinc precursor was different. In S1, the concentration of the zinc stearate in octadecene solution was adjusted from 0.05 M to 0.0125 M, that was, the mole ratio of the kernel of the indium phosphide quantum dot to the first zinc precursor was 1:10.

### Embodiment 4

This embodiment provided a preparation method for a blue indium phosphide quantum dot, which was basically the same as Embodiment 2. The difference lied in that, the addition of the first zinc precursor was different. In S1, the concentration of the zinc stearate in octadecene solution was adjusted from 0.5 M to 0.125 M, that was, the mole ratio of the kernel of the indium phosphide quantum dot to the first zinc precursor was 1:100.

### Embodiment 5

This embodiment provided a preparation method for a blue indium phosphide quantum dot, which was basically the same as Embodiment 2. The difference lied in that, in S1, a solvent was replaced from octadecene to trioctylamine, and the temperature was adjusted from 310° C. to 340° C.

### Embodiment 6

This embodiment provided a preparation method for a blue indium phosphide quantum dot, which was basically the same as Embodiment 2. The difference lied in that, the addition of thiol was different. In S2, the 1-dodecanethiol was added dropwise at 2 mL/h for 0.3 hours, that was, a mole ratio of the first zinc precursor to the thiol was about 1:1.

### Embodiment 7

This embodiment provided a preparation method for a blue indium phosphide quantum dot, which was basically the same as Embodiment 2. The difference lied in that, the addition of thiol was different. In S2, the 1-dodecanethiol was added dropwise at 2 mL/h for 1.4 hours, that was, a mole ratio of the first zinc precursor to the thiol was about 1:5.

### Embodiment 8

This embodiment provided a preparation method for a blue indium phosphide quantum dot, which was basically the same as Embodiment 2. The difference lied in that, the addition of an anionic precursor was different. In S3, the trioctyl phosphine solution of sulfur (the concentration being 2 M) was subjected to a reaction at 10 mL/h and added dropwise for 0.8 hours, that was, a mole ratio of the thiol to TOP-S was 1:2.

### Embodiment 9

This embodiment provided a preparation method for a blue indium phosphide quantum dot, which was basically the same as Embodiment 2. The difference lied in that, the addition of an anionic precursor was different. In S3, the trioctyl phosphine solution of sulfur (the concentration being 2 M) was subjected to a reaction at 10 mL/h and added dropwise for 4 hours, that was, a mole ratio of the thiol to TOP-S was 1:10.

### Embodiment 10

This embodiment provided a preparation method for a blue indium phosphide quantum dot, which was basically the same as Embodiment 5. The difference lied in that, an addition temperature of TOP-S was changed; and in S3, the temperature was heated to 340° C., and then the TOP-S was added.

### Embodiment 11

This embodiment provided a preparation method for a blue indium phosphide quantum dot, which was basically the same as Embodiment 2. The difference lied in that, the addition of an anionic precursor was different. In S3, the trioctyl phosphine solution of sulfur (the concentration being 2 M) was subjected to a reaction at 1 mL/h and added dropwise for 0.5 hours, that was, a mole ratio of the thiol to TOP-S was 1:0.25.

### Embodiment 12

This embodiment provided a preparation method for a blue indium phosphide quantum dot, which was basically the same as Embodiment 2. The difference lied in that, the addition of an anionic precursor was different. In S3, the trioctyl phosphine solution of sulfur (the concentration being 2 M) was subjected to a reaction at 10 mL/h and added dropwise for 0.2 hours, that was, a mole ratio of the thiol to TOP-S was 1:1, and the temperature was cooled to 240° C.

### Embodiment 13

This embodiment provided a preparation method for a blue indium phosphide quantum dot, which was basically the same as Embodiment 2. The difference lied in that, Na—O—C≡P was replaced with K—O—C≡P.

### Embodiment 14

This embodiment provided a preparation method for a blue indium phosphide quantum dot, which was basically the same as Embodiment 2. The difference lied in that, Na—O—C≡P was replaced with Zn—(O—C≡P)₂.

### Embodiment 15

This embodiment provided a preparation method for a blue indium phosphide quantum dot, which was basically the same as Embodiment 2. The difference lied in that, the temperature of an anionic precursor participating a reaction was different; and in S3, the temperature was heated to 285° C., and then TOP-S was added.

### Embodiment 16

This embodiment provided a preparation method for a blue indium phosphide quantum dot, which was basically the same as Embodiment 5. The difference lied in that, the temperature of thiol participating a reaction was different; in S2, 1-dodecanethiol was added dropwise at 240° C. for reaction, and the addition was performed at 5 mL/h for 1 hour; and at the same time, the temperature was continuously heated to 340° C. and maintained until the addition of the 1-dodecanethiol was completed, so as to form a second mixed solution.

### Embodiment 17

This embodiment provided a preparation method for a blue indium phosphide quantum dot, which was basically the same as Embodiment 1. The difference lied in that, the addition of an anionic precursor was different; and in S3, the TOP-S (the concentration being 2 M) was added dropwise at 10 ml/h for 4.5 hours.

### Embodiment 18

This embodiment provided a preparation method for a blue indium phosphide quantum dot, which was basically the same as Embodiment 1. The difference lied in that, the addition of an anionic precursor was different; and in S3, the TOP-S (the concentration being 2 M) was added dropwise at 10 ml/h for 9 hours.

### Embodiment 19

This embodiment provided a preparation method for a blue indium phosphide quantum dot, which was basically the same as Embodiment 1. The difference lied in that, the addition of an anionic precursor was different; and in S3, the TOP-S (the concentration being 2 M) was added dropwise at 10 ml/h for 0.5 hours.

### Embodiment 20

This embodiment provided a preparation method for a blue indium phosphide quantum dot, which was basically the same as Embodiment 1. The difference lied in that, the addition of an anionic precursor was different; and in S3, the TOP-S (the concentration being 2 M) was added dropwise at 10 ml/h for 1.8 hours.

### Embodiment 21

This embodiment provided a preparation method for a blue indium phosphide quantum dot, which was basically the same as Embodiment 1. The difference lied in that, the temperature of an anionic precursor participating a reaction was different; and in S3, the temperature was heated to 240° C., and then TOP-S was added.

### Embodiment 22

This embodiment provided a preparation method for a blue indium phosphide quantum dot, which was basically the same as Embodiment 1. The difference lied in that, the type of anionic precursors was different; and in S3, the added anionic precursor was TOP-Se (the concentration being 2 M).

### Embodiment 23

This embodiment provided a preparation method for a blue indium phosphide quantum dot, which was basically the same as Embodiment 1. The difference lied in that, the type of anionic precursors was different; and in S3, the added anionic precursor was TOP-Se and TOP-S (the concentration being 2 M), which was respectively added dropwise at 5 ml/h for 2 hours.

### Embodiment 24

This embodiment provided a preparation method for a blue indium phosphide quantum dot, which was basically the same as Embodiment 1. The difference lied in that, the addition of 1-dodecanethiol was increased; and in S2, the 1-dodecanethiol was added dropwise at 10 mL/h for 1 hour.

### Embodiment 25

This embodiment provided a preparation method for a blue indium phosphide quantum dot, which was basically the same as Embodiment 1. The difference lied in that, the addition of 1-dodecanethiol was decreased; and in S2, the 1-dodecanethiol was added dropwise at 3 mL/h for 1 hour.

### Embodiment 26

This embodiment provided a preparation method for a blue indium phosphide quantum dot, which was basically the same as Embodiment 1. The difference lied in that, thiol was changed to short-chain thiol; and in S2, the dropwise-added thiol was 1-mercaptooctane.

### Embodiment 27

This embodiment provided a preparation method for a blue indium phosphide quantum dot, which was basically the same as Embodiment 17. The difference lied in that, a zinc source was added in two parts. Specific steps include: S1, preparing 20 mL of a zinc stearate in octadecene solution with the concentration being 0.5 M; and S3, performing cooling to 290° C., adding 20 ml of the 0.5 M zinc stearate in octadecene solution, and then adding TOP-S (the concentration being 2 M) dropwise to a second mixed solution for reaction.

### Comparative Example 1

This comparative example provided a preparation method for an indium phosphide quantum dot, where the following steps was included in specifically: 40 mL of a zinc stearate in octadecene solution with the concentration being 0.5 M was prepared; vacuuming was performed at 120° C. for 30 min; then converted to argon; a temperature was heated to 240° C.; one tenth of the spare kernel (a preparation method being the same as Embodiment 1) was added; after the temperature was re-heated to 240° C., TOP-S (the concentration being 2 M) was added dropwise at 5 mL/h for 1 hour; and at the same time, the temperature was continuously heated to 310° C., and maintained the temperature until the TOP-S was completely added dropwise. Then the temperature was cooled and purification were performed, so as to obtain the indium phosphide quantum dot. An electroluminescent device and a display device were prepared from the blue indium phosphide quantum dot obtained by means of preparation; and the preparation method used a conventional method in the related art, and was not described herein again.

### Comparative Example 2

This comparative example provided a preparation method for an indium phosphide quantum dot, where the following steps was included in specifically: 40 mL of a zinc stearate in octadecene solution with the concentration being 0.5 M was prepared; vacuuming was performed at 120° C. for 30 min; then converted to argon; a temperature was heated to 240° C.; one tenth of the spare kernel (a preparation method being the same as Embodiment 1) was added; after the temperature was re-heated to 240° C., 1-dodecanethiol was added dropwise at 5 mL/h for 1 hour; and at the same time, the temperature was continuously heated to 310° C., and maintained the temperature until the 1-dodecanethiol was completely added dropwise. Then the temperature was cooled and purification were performed, so as to obtain the indium phosphide quantum dot. An electroluminescent device and a display device were prepared from the blue indium phosphide quantum dot obtained by means of preparation; and the preparation method used a conventional method in the related art, and was not described herein again.

The blue indium phosphide quantum dot obtained in Embodiments 1-27 and the indium phosphide quantum dot obtained in Comparative examples 1-2 are respectively prepared into the electroluminescent device; and then a fluorescence spectrum and fluorescence quantum yield of the electroluminescent device are tested.

Specific test results are shown in the following table.

| | Fluorescence | | | | Maximum |
|---|---|---|---|---|---|
| | (photoluminescence) | Electroluminescent | Fluorescence | Electroluminescent | brightness of |
| | emission | emission | quantum | device | electroluminescent |
| | peak PL/nm | peak EL/nm | yield QY/% | EQE/% | device/nits |
| Embodiment | 464 | 470 | 67 | 1.5 | 124 |
| 1 | | | | | |
| Embodiment | 466 | 472 | 75 | 1.8 | 132 |
| 2 | | | | | |
| Embodiment | 476 | 480 | 55 | 1.7 | 142 |
| 3 | | | | | |
| Embodiment | 456 | 462 | 72 | 1.4 | 102 |
| 4 | | | | | |
| Embodiment | 472 | 478 | 77 | 1.4 | 102 |
| 5 | | | | | |
| Embodiment | 472 | 478 | 65 | 1.8 | 265 |
| 6 | | | | | |
| Embodiment | 456 | 462 | 75 | 0.8 | 112 |
| 7 | | | | | |
| Embodiment | 466 | 472 | 75 | 1.4 | 114 |
| 8 | | | | | |
| Embodiment | 466 | 472 | 68 | 1.8 | 325 |
| 9 | | | | | |
| Embodiment | 468 | 474 | 65 | 1.8 | 363 |
| 10 | | | | | |
| Embodiment | 466 | 474 | 73 | 1.4 | 165 |
| 11 | | | | | |
| Embodiment | 466 | 472 | 73 | 1.0 | 134 |
| 12 | | | | | |
| Embodiment | 464 | 460 | 68 | 1.6 | 189 |
| 13 | | | | | |
| Embodiment | 460 | 466 | 75 | 1.4 | 123 |
| 14 | | | | | |
| Embodiment | 472 | 476 | 65 | 1.2 | 132 |
| 15 | | | | | |
| Embodiment | 474 | 478 | 72 | 1.7 | 124 |
| 16 | | | | | |
| Embodiment | 464 | 470 | 65 | 1.6 | 138 |
| 17 | | | | | |
| Embodiment | 464 | 470 | 63 | 1.8 | 153 |
| 18 | | | | | |
| Embodiment | 464 | 470 | 70 | 1.1 | 95 |
| 19 | | | | | |
| Embodiment | 464 | 470 | 68 | 1.1 | 97 |
| 20 | | | | | |
| Embodiment | 462 | 468 | 72 | 0.8 | 98 |
| 21 | | | | | |
| Embodiment | 471 | 476 | 51 | 1.4 | 124 |
| 22 | | | | | |
| Embodiment | 468 | 474 | 62 | 1.4 | 112 |
| 23 | | | | | |
| Embodiment | 462 | 468 | 75 | 0.6 | 42 |
| 24 | | | | | |
| Embodiment | 475 | 480 | 41 | 1.3 | 138 |
| 25 | | | | | |
| Embodiment | 458 | 464 | 78 | 1.2 | 146 |
| 26 | | | | | |
| Embodiment | 466 | 472 | 62 | 1.2 | 117 |
| 27 | | | | | |
| Comparative | 514 | 520 | 31 | 2.5 | 2541 |
| example 1 | | | | | |
| Comparative | 462 | 468 | 64 | 0.1 | 24 |
| example 2 | | | | | |

FIG. 1 shows the absorption spectrum of a blue indium phosphide quantum dot solution according to Embodiment 1.

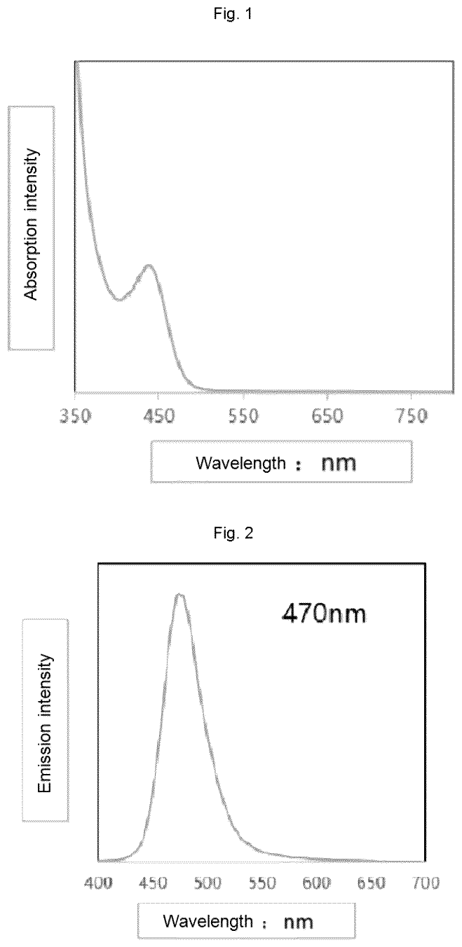

FIG. 2 shows the fluorescence emission spectrum of a device prepared from a blue indium phosphide quantum dot solution according to Embodiment 1.

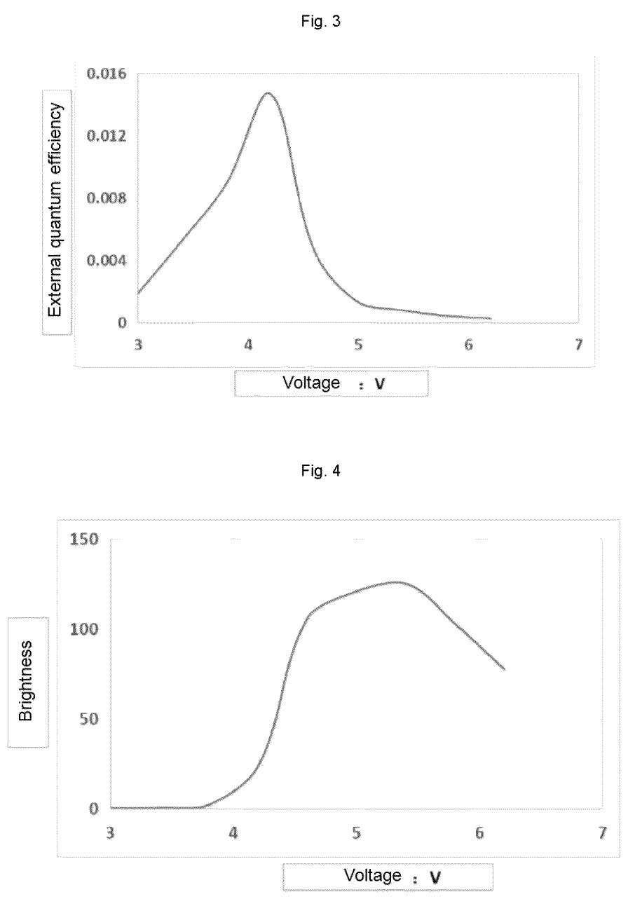

FIG. 3 shows the voltage-EQE change diagram of a prepared electroluminescent device according to Embodiment 1.

FIG. 4 shows the voltage-brightness change diagram of a prepared electroluminescent device according to Embodiment 1.

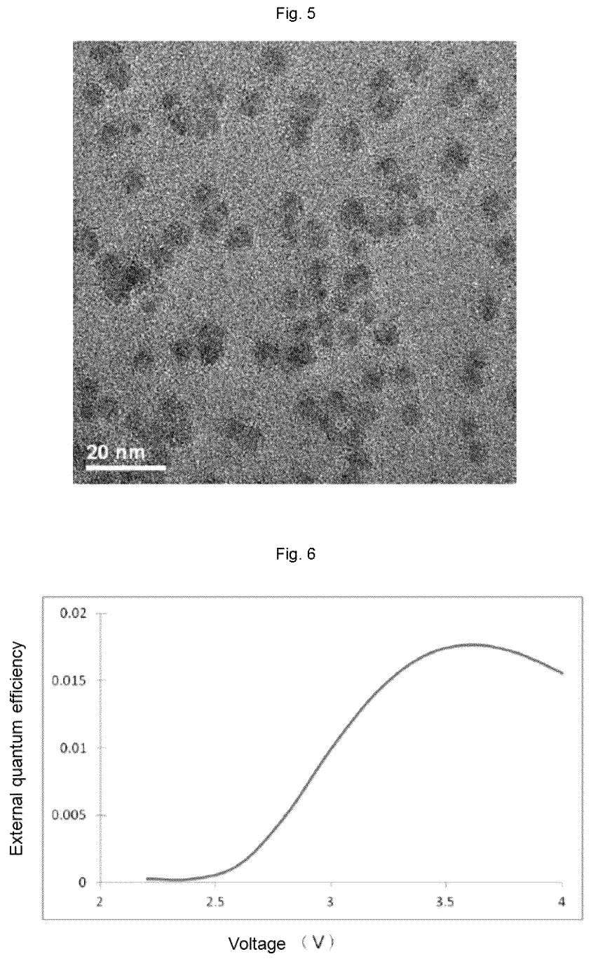

FIG. 5 shows the transmission electron microscope diagram of a blue indium phosphide quantum dot solution according to Embodiment 1.

FIG. 6 shows the voltage-EQE change diagram of a prepared electroluminescent device according to Embodiment 2.

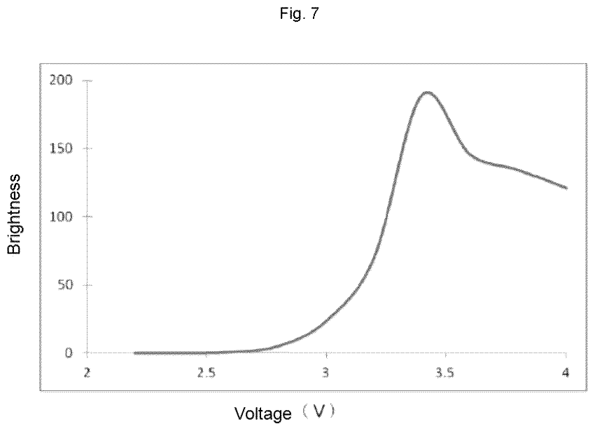

FIG. 7 shows the voltage-brightness change diagram of a prepared electroluminescent device according to Embodiment 2.

It can be seen, from the embodiments and comparative examples, that the blue indium phosphide quantum dot prepared by means of the method of the present application has a pure wavelength; and it can be seen from FIG. 2 that the peak value of a fluorescence emission peak ranges from 450 to 480 nm. When the quantum dot is applied to the electroluminescent device, the brightness is high and greater than 100 nits, and the external quantum efficiency reaches up to 1.8%, such that an application range of the indium phosphide quantum dot is widened.

FIG. 3 is a voltage-EQE change diagram of a prepared electroluminescent device according to Embodiment 1. It can be seen that the maximum EQE is 1.5%. FIG. 6 is a voltage-EQE change diagram of a prepared electroluminescent device according to Embodiment 2. It can be seen that the maximum EQE is 1.8%.

FIG. 4 is a voltage-brightness change diagram of a prepared electroluminescent device according to Embodiment 1. It can be seen that the maximum brightness is 124 nits. FIG. 7 is a voltage-brightness change diagram of a prepared electroluminescent device according to Embodiment 2. It can be seen that the maximum brightness is 132 nits.

The foregoing description of the disclosed embodiments enables a person skilled in the art to implement or use the present disclosure. It is apparent that the person skilled in the art will make many modifications to these embodiments, and the general principles defined in the disclosure may be achieved in the other embodiments without departing from the spirit or scope of the present disclosure. Therefore, the present disclosure will not be limited to the embodiments shown herein, but to conform to the maximum extent of principles and new features that are disclosed herein.

1. A preparation method for a blue indium phosphide quantum dot, comprising the following steps:
S1, mixing the kernel of an indium phosphide quantum dot and a first zinc precursor, so as to form a first mixed solution;
S2, at 300-340° C., adding thiol to the first mixed solution for reaction, so as to form a second mixed solution containing an indium phosphide quantum dot intermediate product; and
S3, at 240-340° C., adding an anionic precursor to the second mixed solution for reaction, so as to obtain a blue indium phosphide quantum dot, wherein
the reaction activity of the anionic precursor is lower than the reaction activity of the thiol.

2. The preparation method for a blue indium phosphide quantum dot according to claim 1, wherein a mole ratio of the kernel of the indium phosphide quantum dot to the first zinc precursor is 1:(10-100); and
preferably, a mole ratio of the first zinc precursor to the thiol is 1:(1-5).

3. The preparation method for a blue indium phosphide quantum dot according to claim 1, wherein a mole ratio of the thiol to the anionic precursor is 1:(2-10), excluding 1:2; and a reaction temperature in S3 is 280-340° C., excluding 280° C.

4. The preparation method for a blue indium phosphide quantum dot according to claim 1, wherein a mole ratio of the thiol to the anionic precursor is 1:(0-2), excluding 1:0; and/or a reaction temperature in S3 is 240-280° C.

5. The preparation method for a blue indium phosphide quantum dot according to claim 1, wherein the first zinc precursor is a zinc precursor which is not decomposed into zinc oxide above 300° C.; and
preferably, the first zinc precursor is zinc halide or zinc fatty acid.

6. The preparation method for a blue indium phosphide quantum dot according to claim 1, wherein the anionic precursor is a liganded or unliganded solution of selenium and/or sulfur.

7. The preparation method for a blue indium phosphide quantum dot according to claim 1, wherein a preparation method for the kernel of the indium phosphide quantum dot comprises: mixing an indium precursor, a phosphorous precursor, a second zinc precursor and an organic solvent, and performing reaction at 110-160° C., so as to obtain a solution containing the kernel of the indium phosphide quantum dot; and obtaining the kernel of the indium phosphide quantum dot by means of purification, wherein a chemical structural formula of the phosphorous precursor is represented as M-(O—C≡P)ₙ, and M is a metal element, n is 1, 2 or 3; preferably, the M is one of the metal elements Li, Na, K, Zn and Ga; and more preferably, the phosphorous precursor is represented as Li—O—C≡P, Na—O—C≡P, K—O—C≡P Zn—(O—C≡P)₂ or Ga—(O—C≡P)₃.

8. A blue indium phosphide quantum dot, obtained by means of the preparation method according to claim 1, wherein the wavelength of the blue indium phosphide quantum dot is 450-480 nm.

9. An electroluminescent device, comprising a light-emitting layer, wherein the blue indium phosphide quantum dot according to claim 8 is used as the light-emitting layer; and the external quantum efficiency of the electroluminescent device is greater than 0.5%, and the maximum brightness is greater than 100 nits.

10. A display device, comprising the electroluminescent device according to claim 9.

11. The preparation method for a blue indium phosphide quantum dot according to claim 2, wherein the first zinc precursor is a zinc precursor which is not decomposed into zinc oxide above 300° C.; and
preferably, the first zinc precursor is zinc halide or zinc fatty acid.

12. The preparation method for a blue indium phosphide quantum dot according to claim 3, wherein the first zinc precursor is a zinc precursor which is not decomposed into zinc oxide above 300° C.; and
preferably, the first zinc precursor is zinc halide or zinc fatty acid.

13. The preparation method for a blue indium phosphide quantum dot according to claim 4, wherein the first zinc precursor is a zinc precursor which is not decomposed into zinc oxide above 300° C.; and
preferably, the first zinc precursor is zinc halide or zinc fatty acid.

14. The preparation method for a blue indium phosphide quantum dot according to claim 2, wherein the anionic precursor is a liganded or unliganded solution of selenium and/or sulfur.

15. The preparation method for a blue indium phosphide quantum dot according to claim 3, wherein the anionic precursor is a liganded or unliganded solution of selenium and/or sulfur.

16. The preparation method for a blue indium phosphide quantum dot according to claim 4, wherein the anionic precursor is a liganded or unliganded solution of selenium and/or sulfur.

17. The preparation method for a blue indium phosphide quantum dot according to claim 2, wherein a preparation method for the kernel of the indium phosphide quantum dot comprises: mixing an indium precursor, a phosphorous precursor, a second zinc precursor and an organic solvent, and performing reaction at 110-160° C., so as to obtain a solution containing the kernel of the indium phosphide quantum dot; and obtaining the kernel of the indium phosphide quantum dot by means of purification, wherein a chemical structural formula of the phosphorous precursor is represented as M-(O—C≡P), and M is a metal element, n is 1, 2 or 3; preferably, the M is one of the metal elements Li, Na, K, Zn and Ga; and more preferably, the phosphorous precursor is represented as Li—O—C≡P, Na—O—C≡P, K—O—C≡P, Zn—(O—C≡P)₂ or Ga—(O—C≡P)₃.

18. The preparation method for a blue indium phosphide quantum dot according to claim 3, wherein a preparation method for the kernel of the indium phosphide quantum dot comprises: mixing an indium precursor, a phosphorous precursor, a second zinc precursor and an organic solvent, and performing reaction at 110-160° C., so as to obtain a solution containing the kernel of the indium phosphide quantum dot; and obtaining the kernel of the indium phosphide quantum dot by means of purification, wherein a chemical structural formula of the phosphorous precursor is represented as M-(O—C≡P)ₙ, and 1 M is a metal element, n is 1, 2 or 3; preferably, the M is one of the metal elements Li, Na, K, Zn and Ga; and more preferably, the phosphorous precursor is represented as Li—O—CP, Na—O—C≡P, K—O—C≡P, Zn—(O—C≡P)₂ or Ga—(O—C≡P)₃.

19. The preparation method for a blue indium phosphide quantum dot according to claim 4, wherein a preparation method for the kernel of the indium phosphide quantum dot comprises: mixing an indium precursor, a phosphorous precursor, a second zinc precursor and an organic solvent, and performing reaction at 110-160° C., so as to obtain a solution containing the kernel of the indium phosphide quantum dot; and obtaining the kernel of the indium phosphide quantum dot by means of purification, wherein a chemical structural formula of the phosphorous precursor is represented as M-(O—C≡P)ₙ, and M is a metal element, n is 1, 2 or 3; preferably, the M is one of the metal elements Li, Na, K, Zn and Ga; and more preferably, the phosphorous precursor is represented as Li—O—C≡P, Na—O—C≡P, K—O—C≡P, Zn—(O—C≡P)₂ or Ga—(O—C≡P)₃.
